(19) United States
(12) Patent Application Publication
(10) Pub. No.: US 2026/0293471 A1
(43) Pub. Date: Sep. 24, 2026

(54) DISPLAY PANEL AND DISPLAY DEVICE

(71) Applicant: Wuhan Tianma Microelectronics Co., Ltd., Wuhan (CN)

(72) Inventor: Xue LI, Wuhan (CN)

(73) Assignee: Wuhan Tianma Microelectronics Co., Ltd., Wuhan (CN)

(21) Appl. No.: 19/686,183

(22) Filed: May 22, 2026

(30) Foreign Application Priority Data
Dec. 10, 2025 (CN) 202511862792.8

(51) Int. Cl. H10K 59/131; H10K 59/122

(52) U.S. Cl. CPC H10K 59/131; H10K 59/122

(57) ABSTRACT

A display panel and a display device. The display panel includes a display region, a non-display region, a substrate, a first metal layer, a first film layer, a cathode, and a first barrier. The first metal layer includes a first signal line located in the first non-display region. The first film layer is located on a side of the first metal layer away from the substrate, and overlaps the display region and the first non-display region. The cathode overlaps display region and first non-display region. The first non-display region includes a first region and a second region. The display region, first region, second region and first barrier are arranged along first direction. The second region includes a first sub-region. The first sub-region includes a first signal line. The first film layer overlaps first region and first sub-region. The first film layer overlaps first signal line in first sub-region.

### CROSS-REFERENCE TO RELATED APPLICATIONS

The present application claims priority to Chinese Patent Application No. 202511862792.8, entitled “DISPLAY PANEL AND DISPLAY DEVICE”, filed on Dec. 10, 2025, the content of which is incorporated herein by reference in its entirety.

### TECHNICAL FIELD

The present disclosure relates to the field of display technologies, and in particular, to a display panel and a display device.

### BACKGROUND

In a display panel, a cathode serves as a key electrode structure of a light-emitting device, and its structural reliability greatly affects the display effect of the display panel.

At present, in order to ensure the light emission uniformity of the display region, the cathode usually needs to extend to the frame region at the periphery of the display region, but this causes a risk of short circuit between the cathode and some signal lines in a lower frame, thereby affecting the performance of the panel.

### SUMMARY

Embodiments of the present disclosure provide a display panel and a display device for avoiding short circuit between a cathode and a signal line in a lower frame.

In an aspect, the present disclosure provides a display panel. The display panel includes a display region and a non-display region, a substrate, a first metal layer, a first film layer, a cathode, and a first barrier. The non-display region includes a first non-display sub-region. The first non-display sub-region is located on a side of the display region along a first direction. The first metal layer is located on a side of the substrate. The first metal layer includes a first signal line. The first signal line is located in the first non-display sub-region and transmits a first signal. The first film layer is located on a side of the first metal layer away from the substrate. The first film layer overlaps the display region and the first non-display sub-region along a direction perpendicular to a plane of the substrate. The cathode is located on a side of the first film layer away from the substrate. The cathode transmits a second signal. The second signal is different from the first signal. The cathode overlaps the display region and the first sub-non-display region along the direction perpendicular to the plane of the substrate. The first barrier is at least located in the first non-display region. The first non-display sub-region includes a first region and a second region. The display region, the first region, the second region and the first barrier are sequentially arranged along the first direction. The second region includes a first sub-region. The first sub-region includes the first signal line. The first film layer overlaps the first region and the first sub-region along the direction perpendicular to the plane of the substrate. The first film layer at least overlaps the first signal line in the first sub-region. A film thickness of the first film layer in the first sub-region is smaller than a film thickness of the first film layer in the first region.

In another aspect, the present disclosure provides a display device. The display device includes a display panel. he display panel includes a display region and a non-display region, a substrate, a first metal layer, a first film layer, a cathode, and a first barrier. The non-display region includes a first non-display sub-region. The first non-display sub-region is located on a side of the display region along a first direction. The first metal layer is located on a side of the substrate. The first metal layer includes a first signal line. The first signal line is located in the first non-display sub-region and transmits a first signal. The first film layer is located on a side of the first metal layer away from the substrate. The first film layer overlaps the display region and the first non-display sub-region along a direction perpendicular to a plane of the substrate. The cathode is located on a side of the first film layer away from the substrate. The cathode transmits a second signal. The second signal is different from the first signal. The cathode overlaps the display region and the first sub-non-display region along the direction perpendicular to the plane of the substrate. The first barrier is at least located in the first non-display region. The first non-display sub-region includes a first region and a second region. The display region, the first region, the second region and the first barrier are sequentially arranged along the first direction. The second region includes a first sub-region. The first sub-region includes the first signal line. The first film layer overlaps the first region and the first sub-region along the direction perpendicular to the plane of the substrate. The first film layer at least overlaps the first signal line in the first sub-region. A film thickness of the first film layer in the first sub-region is smaller than a film thickness of the first film layer in the first region.

### BRIEF DESCRIPTION OF DRAWINGS

In order to more clearly illustrate the embodiments of the present disclosure or the technical solutions in the prior art, the accompanying drawings are briefly introduced as below. The accompanying drawings in the following description are some embodiments of the present disclosure, and for those skilled in the art, other accompanying drawings may be obtained according to these accompanying drawings.

FIG. 1 is a schematic diagram of a display panel in the related art;

FIG. 2 is a cross-sectional view of FIG. 1 along line A1-A2 in the related art;

FIG. 3 is a schematic diagram of a display panel according to an embodiment of the present disclosure;

FIG. 4 is schematic diagram of a display panel according to another embodiment of the present disclosure;

FIG. 5 is schematic diagram of a display panel according to another embodiment of the present disclosure;

FIG. 6 is a cross-sectional view of FIG. 5 along line B1-B2 according to an embodiment of the present disclosure;

FIG. 7 is schematic diagram of a display panel according to another embodiment of the present disclosure;

FIG. 8 is schematic diagram of a display panel according to another embodiment of the present disclosure;

FIG. 9 is schematic diagram of a display panel according to another embodiment of the present disclosure;

FIG. 10 is a cross-sectional view of FIG. 9 along line C1-C2 according to an embodiment of the present disclosure;

FIG. 11 is schematic diagram of a display panel according to another embodiment of the present disclosure;

FIG. 12 is a cross-sectional view of FIG. 11 along line D1-D2 according to an embodiment of the present disclosure;

FIG. 13 is schematic diagram of a display panel according to another embodiment of the present disclosure;

FIG. 14 is schematic diagram of a display panel according to another embodiment of the present disclosure;

FIG. 15 is schematic diagram of a display panel according to another embodiment of the present disclosure;

FIG. 16 is a cross-sectional view of FIG. 14 along line E1-E2 according to an embodiment of the present disclosure;

FIG. 17 is a cross-sectional view of FIG. 14 along line F1-F2 according to an embodiment of the present disclosure;

FIG. 18 is schematic diagram of a display panel according to another embodiment of the present disclosure;

FIG. 19 is schematic diagram of a display panel according to another embodiment of the present disclosure;

FIG. 20 is schematic diagram of a display panel according to another embodiment of the present disclosure; and

FIG. 21 is a structural schematic diagram of a display device according to an embodiment of the present disclosure.

### DESCRIPTION OF EMBODIMENTS

In order to better understand technical solutions of the present disclosure, embodiments of the present disclosure are described in detail below in conjunction with the drawings.

It should be clear that the described embodiments are merely some of the embodiments of the present disclosure rather than all of the embodiments. All other embodiments obtained by those skilled in the art according to the embodiments of the present disclosure should fall within the protection scope of the present disclosure.

Terms used in the embodiments of the present disclosure are merely for the purpose of describing embodiments, but not intended to limit the present disclosure. Singular forms of “a/an”, “said” and “the” used in the embodiments of the present disclosure and the attached claims are also intended to include plural forms thereof, unless noted otherwise.

It should be understood that the term “and/or” used in the context of the present disclosure is to describe a correlation relation of related objects, indicating that there can be three relations, e.g., A and/or B can indicate only A, both A and B, and only B. In addition, the symbol “/” in the context generally indicates that the relation between the objects in front and at the back of “/” is an “or” relationship.

Before illustrating the technical solutions provided by the embodiments of the present disclosure, the present disclosure first introduces issues existing in the related art.

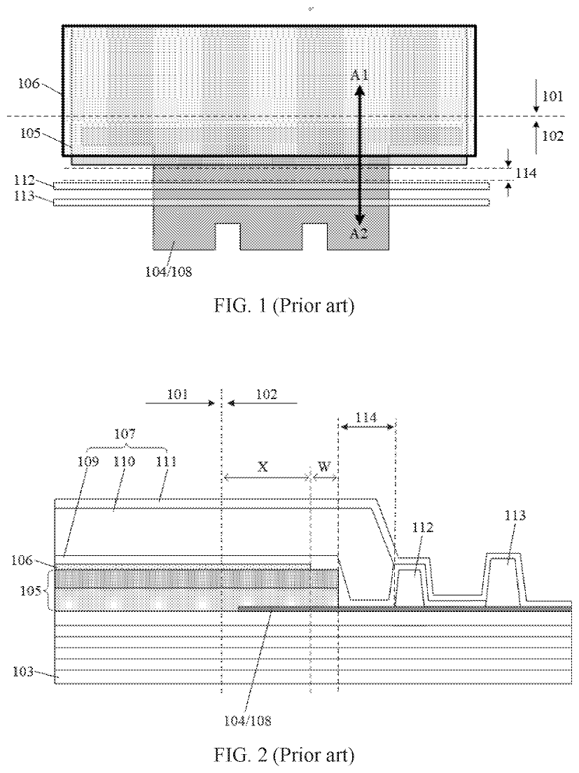

FIG. 1 is a schematic diagram of a display panel in the related art. FIG. 2 is a cross-sectional view of the display panel in FIG. 1 along line A1-A2. As shown in FIG. 1 and FIG. 2, the display panel includes a display region 101 and a lower frame region 102.

The display panel further includes a substrate 103, a first metal layer 104, a first film layer 105 located on a side of the first metal layer 104 away from the substrate 103, a cathode 106 located on a side of the first film layer 105 away from the substrate 103, and an encapsulation layer 107 located on a side of the cathode 106 away from the substrate 103.

The first metal layer 104 includes a first bus 108 at least located in the lower frame region 102. The first bus 108 is electrically connected to the display function trace in the display region 101. The first bus 108 is configured to transmit a required signal to the display function trace, where a signal transmitted by the first bus 108 is different from a cathode signal.

The encapsulation layer 107 includes a first inorganic encapsulation layer 109, an organic encapsulation layer 110, and a second inorganic encapsulation layer 111 that are stacked.

The display panel further includes a first barrier 112 and a second barrier 113. The first barrier 112 and the second barrier 113 are at least located in the lower frame region 102. The first barrier 112 is located between the display region 101 and the second barrier 113.

The lower frame region 102 includes a clearance region 114 located between the display region 101 and the first barrier 112. The first film layer 105 is removed in the clearance region 114, thereby forming the first barrier 112 by using the step difference of the film layer, and forming the pit structure in the clearance region 114 by using the step difference of the film layer. The pit structure is configured to suppress the flow of the organic encapsulation material in the manufacturing process of the organic encapsulation layer 110, so as to prevent the organic encapsulation material from overflowing.

In the manufacturing process of the cathode, considering problems such as the incoming material precision and the shadow during evaporation, a certain deviation may exist in an actual coverage position of the cathode. Therefore, the cathode film-forming region is generally designed to extend beyond the display region 101, thereby enabling the finally formed cathode to cover each pixel region.

At present, at the lower frame region 102, the cathode film-forming region needs to be at least extend beyond the display region 90 μm, that is, a distance between the boundary of the cathode film-forming region and the display region 101 needs to be designed to be greater than or equal to 90 μm, corresponding to the structure, the distance can also be understood as a distance X between an edge of the cathode 106 and the display region 101.

However, with the development of narrow frame technology, the width of the lower frame of the display panel is gradually decreasing. On the premise of ensuring a safe distance between the boundary of the cathode film-forming region and the display region 101, a distance between the cathode film-forming region and the clearance region 114 will be compressed.

Table 1 shows various sizes of the 7 products A to G. In conjunction with Table 1, it can be seen that in product F, when a width of the lower frame region 102 is 0.9 mm, after satisfying a condition that the distance between the boundary of the cathode film-forming region and the display region 101 is greater than or equal to 90 μm, the distance between the cathode film-forming region and the clearance region 114 is reduced to be smaller than or equal to 70 μm, and corresponding to the structure, the distance may also be understood as the distance W between the cathode 106 and the clearance region 114. However, when the distance between the cathode film-forming region and the clearance region is smaller than or equal to 90 μm, the cathode evaporation material may easily extend into the clearance region, resulting in short circuit between the cathode 106 and the exposed first bus 108, thereby causing defects such as burnout and abnormal display.

TABLE 1

| Product | A | B | C | D | E | F | G |
|---|---|---|---|---|---|---|---|
| Width (μm) of the | 1.4 | 1.3 | 1.2 | 1.1 | 1.0 | 0.9 | 0.8 |
| lower frame region | | | | | | | |
| Distance (μm) between | 530 | 513 | 432.1 | 425 | 278.7 | 183.1 | 151.2 |
| display region and | | | | | | | |
| clearance region | | | | | | | |
| Width (μm) of the | 50 | 50 | 50 | 50 | 50 | 20 | 20 |
| clearance zone | | | | | | | |
| Distance (μm) between | 343.7 | 330 | 294 | 295 | 150 | 113.1 | 90 |
| the boundary of the | | | | | | | |
| cathode film-forming | | | | | | | |
| region and the display | | | | | | | |
| region | | | | | | | |
| Distance (μm) between | 190 | 183.7 | 138.1 | 130 | 128.7 | 70 | 61.2 |
| the cathode film- | | | | | | | |
| forming region and the | | | | | | | |
| clearance region | | | | | | | |

In this regard, an embodiment of the present disclosure provides a technical solution, which can effectively alleviate the above problems.

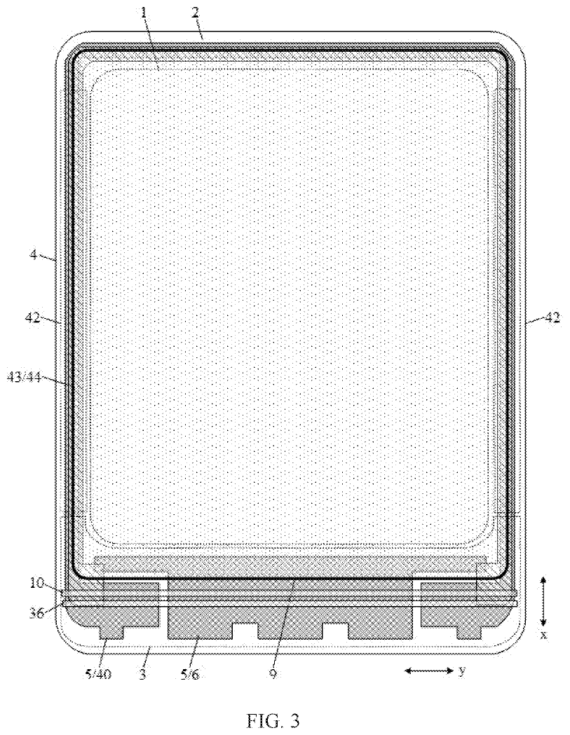

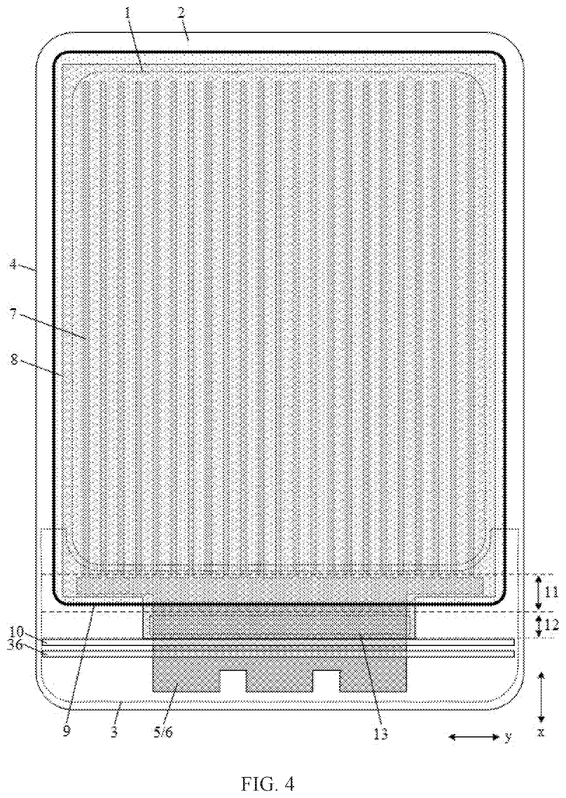

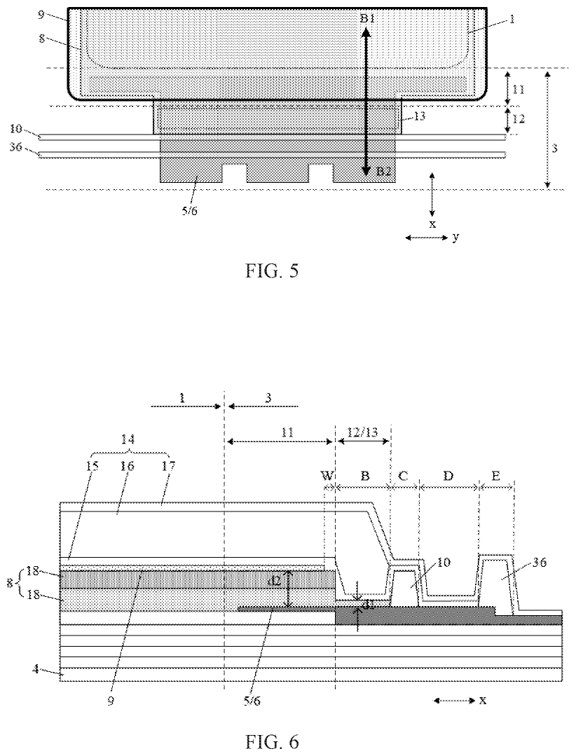

An embodiment of the present disclosure provides a display panel. FIG. 3 is a schematic diagram of a display panel according to an embodiment of the present disclosure. FIG. 4 is schematic diagram of a display panel according to another embodiment of the present disclosure. FIG. 5 is schematic diagram of a display panel according to another embodiment of the present disclosure. FIG. 6 is a cross-sectional view of FIG. 5 along line B1-B2. As shown in FIG. 3 to FIG. 6, the display panel may be an organic light-emitting diode (OLED) display panel, such as an active matrix organic light-emitting diode (AMOLED) display panel.

As shown in FIG. 3 to FIG. 6, the display panel includes a display region 1 and a non-display region 2. The non-display region 2 includes a first non-display sub-region 3. The first non-display sub-region 3 is located on a side of the display region 1 along the first direction x and is a lower frame region.

The display panel further includes a substrate 4 and a first metal layer 5 located on a side of the substrate 4. The first metal layer 5 includes a first signal line 6. The first signal line 6 is located in the first non-display region 3 and transmits a first signal. The first signal line 6 may be electrically connected to the display function trace 7 in the display region 1, for example, electrically connected to the power line. Additionally, the first signal line 6 is configured to transmit the power signal pvdd output by the pin to the power line.

The display panel further includes a first film layer 8 located on a side of the first metal layer 5 away from the substrate 4. The first film layer 8 is in contact with the first metal layer 5. Along the direction perpendicular to the plane of the substrate 4, the first film layer 8 overlaps the display region 1 and the first non-display sub-region 3.

The display panel further includes a cathode 9 located on a side of the first film layer 8 away from the substrate 4. The cathode 9 transmits a second signal. The second signal is a cathode signal pvee, and the second signal is different from the first signal. Along the direction perpendicular to the plane of the substrate 4, the cathode 9 overlaps the display region 1 and the first non-display sub-region 3.

The display panel further includes a first barrier 10 at least located in the first non-display region 3.

The first non-display region 3 includes a first region 11 and a second region 12. The display region 1, the first region 11, the second region 12 and the first barrier 10 are sequentially arranged along the first direction x.

The second region 12 includes a first sub-region 13. The first sub-region 13 includes a first signal line 6. That is, the first sub-region 13 is a region in which the first signal line 6 is disposed in the second region 12. Along the direction perpendicular to the plane of the substrate 4, the first film layer 8 overlaps the first region 11 and the first sub-region 13. In the first sub-region 13, the first film layer 8 at least overlaps the first signal line 6, for example, the first film layer 8 covers the first signal line 6. Additionally, the film thickness d1 of the first film layer 8 in the first sub-region 13 is smaller than the film thickness d2 of the first film layer 8 in the first region 11. It should be noted that the film thicknesses of the film layers in this embodiment of the present disclosure refer to thicknesses of the film layers along the direction perpendicular to the plane of the substrate 4.

In an embodiment of the present disclosure, the first non-display sub-region 3 includes a first region 11 and a second region 12, and the second region 12 is located between the first region 11 and the first barrier 10. One side of the first signal line 6 close to the display region 1 is connected to the display function trace 7 in the display region 1, and the other side of the first signal line 6 extends from at least the first region 11 and the second region 12 to one side of the first barrier 10 away from the display region 1 and is connected to a pin. The second region 12 includes a first sub-region 13. The first signal line 6 extends in the second region 12 in the first sub-region 13.

In an embodiment of the present disclosure, the first film layer 8 adjacent above the first signal line 6 is located in the first region 11 and the first sub-region 13. In the first sub-region 13, the first film layer 8 overlaps the first signal line 6, so as to cover the first signal line 6 in the first sub-region 13, thereby preventing this portion of the first signal line 6 from being exposed. In this way, even if a distance between a boundary of the cathode film-forming region and the second region 12 is compressed due to the narrowing of the frame, causing an evaporation material of the cathode 9 to extend to overlap the first signal line 6, the first film layer 8 can still be used to prevent the cathode 9 from being short-circuited with the first signal line 6, thereby effectively improving the performance and yield of the display panel, especially improving the performance and yield of the narrow-frame display panel.

Further, in an embodiment of the present disclosure, the film thickness of the first film layer 8 in the first sub-region 13 is further configured to be smaller than the film thickness of the first film layer 8 in the first region 11, that is, this portion of the first film layer 8 in the first sub-region 13 is thinned, such that the first film layer 8 only has a smaller thickness. Furthermore, a relatively large step difference is still maintained between the film layer structure in the first sub-region 13 and the film layer structure in the first region 11, as well as between the film structure in the first sub-region 13 and the first barrier 10, and the relatively large step difference can enable the pit structure formed in the first sub-region 13 to have a sufficient depth, thereby effectively suppressing a flow of an organic encapsulation material by better utilizing the pit structure in the manufacturing process of an encapsulation layer. Specifically, the display panel further includes an encapsulation layer 14 located on a side of the cathode 9 away from the substrate 4. The encapsulation layer 14 includes a first inorganic encapsulation layer 15, an organic encapsulation layer 16, and a second inorganic encapsulation layer 17 that are stacked. In the manufacturing process of the organic encapsulation layer 16, the organic encapsulation material fills the pit structure in the second region 12 to prevent overflow thereof.

In other words, in an embodiment of the present disclosure, based on the design of the first film layer 8, the problem of short circuit between the cathode 9 and the first signal line 6 can be avoided, and therefore, the boundary of the cathode film-forming region does not need to be limited by the risk of short circuit between the cathode 9 and the first signal line 6: the distance between the boundary of the cathode film-forming region and the display region 1 can be further increased, allowing the cathode film-forming region to extend beyond the display region 1 more, thereby optimizing the film-forming effect of the cathode 9. Additionally, the design of the width of the lower frame does not need to be limited by the risk of the short circuit between the cathode 9 and the first signal line 6: the distance between the cathode film-forming region and the second region 12 may be reduced, for example, to 90 μm or less, and even there may be an overlap between the cathode film-forming region and the second region 12. Therefore, the lower frame may be further narrowed, for example, to 0.9 mm or less, resulting in an ultra-narrow frame.

In an embodiment, referring to FIG. 6, the film thickness d1 of the first film layer 8 in the first sub-region 13 is greater than or equal to 0.6 μm and smaller than or equal to 1.1 μm.

A minimum thickness of the first film layer 8 in the first sub-region 13 is 0.6 μm, which can prevent this part of the first film layer 8 from being too thin, so that this part of the first film layer 8 plays a more reliable insulating role. For example, this part of the first film layer 8 can have a sufficient thickness to cover a step at an edge of the first signal line 6, further reducing a risk of a short circuit between the cathode 9 and the first signal line 6. A maximum thickness of the first film layer 8 in the first sub-region 13 is designed to be 1.1 μm, which can further prevent this part of the first film layer 8 from being too thick and causing an excessive increase in the height of the film layer in the first sub-region 13, thereby ensuring that the pit structure in the second region 12 has a sufficient depth to suppress the flow of the organic encapsulation material.

In an embodiment, referring to FIG. 6, the first film layer 8 includes at least two sub-layers 18, the first sub-region 13 includes at least one sub-layer 18. A number of sub-layers 18 included in the first sub-region 13 is smaller than a number of sub-layers 18 included in the first region 11.

That is, in the first sub-region 13, a portion of the sub-layer 18 in the first film layer 8 is removed. After removing the portion of the sub-layer 18, the first film layer 8 in the first sub-region 13 is thinned to a larger degree, resulting in a larger step difference between the first sub-region 13 and the peripheral region.

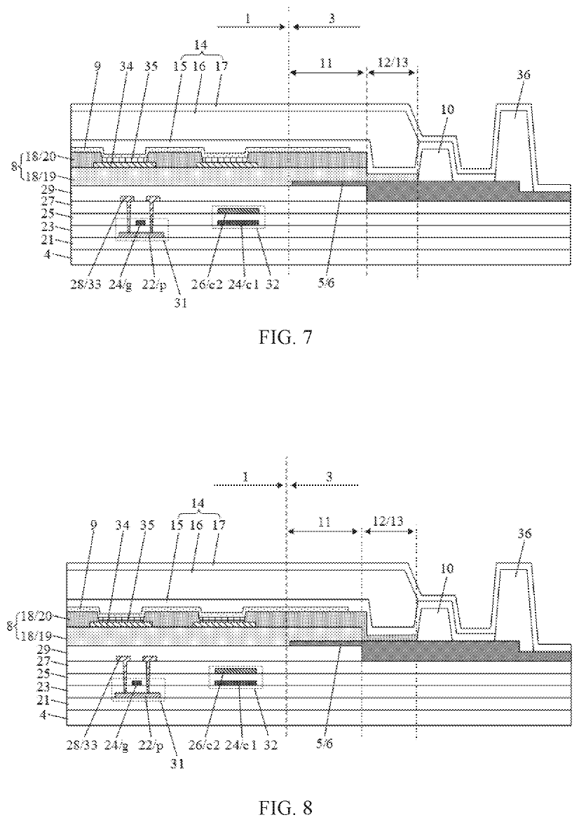

FIG. 7 is schematic diagram of a display panel according to another embodiment of the present disclosure. FIG. 8 is schematic diagram of a display panel according to another embodiment of the present disclosure. As shown in FIG. 7 and FIG. 8, the at least two sub-layers 18 in the first film layer 8 include a planarization layer 19 and a pixel definition layer 20 located on a side of the planarization layer 19 away from the substrate 4.

In a panel structure, the display panel includes a buffer layer 21, a semiconductor layer 22, a first insulating layer 23, a gate metal layer 24, a second insulating layer 25, an electrode metal layer 26, a third insulating layer 27, a source-drain metal layer 28, a fourth insulating layer 29, a first metal layer 5, and a planarization layer 19 that are stacked along a direction away from the substrate 4.

The semiconductor layer 22 includes an active layer p of the transistor 31. The gate metal layer 24 includes a gate g of the transistor 31 and a first electrode plate c1 of the capacitor 32. The electrode metal layer 26 includes a second electrode plate c2 of the capacitor 32. The first source-drain metal layer 28 includes a connection electrode 33 connected to the active layer of the transistor 31.

The display panel further includes an anode 34 and a light-emitting layer 35. The pixel definition layer 20 is located on a side of the anode 34 away from the substrate 4. The pixel definition layer includes an opening. The anode 34 is located on a side of the planarization layer 19 away from the substrate 4 and at least overlaps the opening along the direction perpendicular to the plane of the substrate 4. The light-emitting layer 35 is located in the opening.

The first region 11 includes the planarization layer 19 and the pixel definition layer 20. The first sub-region 13 includes the planarization layer 19 or the pixel definition layer 20. That is, one of the planarization layer 19 and the pixel definition layer 20 is removed in the first sub-region 13.

The planarization layer 19 and the pixel definition layer 20 are both organic film layers, and the organic film layers are usually relatively thick. One of the planarization layer 19 and the pixel definition layer 20 is removed in the first sub-region 13, then it can be ensured that a relatively large step difference is formed between the first sub-region 13 and the periphery, thereby ensuring that the pit structure has a sufficient depth.

In an embodiment, referring to FIG. 7, the first sub-region 13 includes the planarization layer 19 and does not include the pixel definition layer 20. The planarization layer 19 is located below the pixel definition layer 20. When the planarization layer 19 is located in both the first region 11 and the first sub-region 13, the film layers in the two regions have better flatness.

Alternatively, in an embodiment, referring to FIG. 8, the first sub-region 13 includes the pixel definition layer 20 and does not include the planarization layer 19.

In a structure, the first barrier 10 is formed by stacking a film layer material of the pixel definition layer 20 and a film layer material of a support layer. The support layer is configured to form a support structure. The support structure is configured to support a mask in the manufacturing process of the light-emitting layer 35. In a process, the pixel definition layer 20 and the support layer are subjected to simultaneous patterning treatment in a same halftone mask process, that is, after forming a whole layer of the pixel definition layer 20 and a whole layer of the support layer, the two film layers are patterned simultaneously through a same patterning process. The pixel definition layer 20 in the first sub-region 13 may be implemented based on the manufacturing process. After being processed based on this process, the support layer in the first sub-region 13 is removed, and only the material of the pixel definition layer 20 remains.

In an embodiment, referring to FIG. 7 and FIG. 8, in the at least one sub-layer 18, the sub-layer 18 is a single-layer film structure and is located in the first region 11 and the first sub-region 13, and a film thickness of the at least one sub-layer 18 in the first sub-region 13 is smaller than a film thickness of the sub-layer 18 in the first region 11.

Exemplarily, referring to FIG. 7, when the first sub-region 13 includes the planarization layer 19 and does not include the pixel definition layer 20, a film thickness of the planarization layer 19 in the first sub-region 13 is smaller than a film thickness of the planarization layer 19 in the first region 11. For example, the conventional thickness of the planarization layer 19 may be about 2 μm. The planarization layer 19 in the first sub-region 13 may be thinned to be greater than or equal to 0.6 μm and smaller than or equal to 1.1 μm in this embodiment of the present disclosure.

Referring to FIG. 8, when the first sub-region 13 includes the pixel definition layer 20 and does not include the planarization layer 19, the film thickness of the pixel definition layer 20 in the first sub-region 13 is smaller than the film thickness of the pixel definition layer 20 in the first region 11. For example, a conventional total thickness of the pixel definition layer 20 and the support layer is around 2.8 μm. After patterning the pixel definition layer 20 and the support layer, only the pixel definition layer 20 is included in the first sub-region 13. The thickness of the pixel definition layer 20 in the first sub-region 13 is thinned to be greater than or equal to 0.6 μm and smaller than or equal to 1.1 μm, and is smaller than an original thickness of the pixel definition layer 20.

On the basis of reducing the number of sub-layers in the first sub-region 13, further thinning the thickness of the sub-layer 18 in the first sub-region 13 can further increase the step difference between the first sub-region 13 and the peripheral region, thereby increasing the depth of the pit structure.

In an embodiment, referring to FIG. 7 and FIG. 8, the fourth insulating layer 29 may also be removed in the first sub-region 13, thereby resulting in a larger film thickness of the first signal line 6 in the first sub-region 13 when the first signal line 6 is formed, and thus reducing the load of the first signal line 6 and optimizing signal transmission.

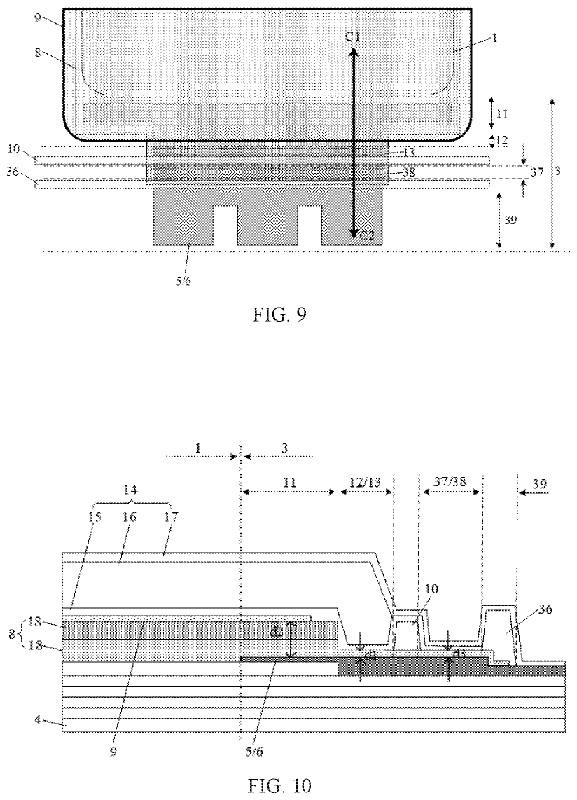

FIG. 9 is schematic diagram of a display panel according to another embodiment of the present disclosure. FIG. 10 is a cross-sectional view of FIG. 9 along line C1-C2. As shown in FIG. 9 and FIG. 10, the display panel further includes a second barrier 36 located on a side of the first barrier 10 away from the display region 1.

The first non-display region 3 further includes a third region 37 located between the first barrier 10 and the second barrier 36. The third region 37 includes a second sub-region 38. The second sub-region 38 includes a first signal line 6. That is, the second sub-region 38 is a region in which the first signal line 6 is disposed in the third region 37. Along the direction perpendicular to the plane of the substrate 4, the first film layer 8 further overlaps the first signal line 6 in the second sub-region 38, and the film thickness d3 of the first film layer 8 in the second sub-region 38 is smaller than the film thickness d2 of the first film layer 8 in the first region 11, for example, the film thickness d3 of the first film layer 8 in the second sub-region 38 is equal to the film thickness d1 of the first film layer 8 in the first sub-region 13.

In the related art, referring to FIG. 1 and FIG. 2, during the continuous compression of the lower frame region 102, the cathode evaporation material may also be short-circuited with the first signal line 6 exposed between the first barrier 112 and the second barrier 113.

Therefore, in an embodiment of the present disclosure, the first film layer 8 is further configured to overlap the second sub-region 38, thereby covering the first signal line 6 at the position with the second sub-region 38, and thus preventing the first signal line 6 from being short-circuited with the cathode 9. Further, the thickness of the first film layer 8 in the second sub-region 38 is smaller than the thickness of the first film layer 8 in the first region 11, thereby resulting in a relatively large step difference between the film layer structure in the second sub-region 38 and the first barrier 10, and a relatively large step difference between the film layer structure in the second sub-region 38 and the second barrier 36, enabling a relatively deep pit structure to be formed at the second sub-region 38. The pit structure is configured to further restrict the flow of the organic encapsulation material, thereby preventing the organic encapsulation material from flowing outside the second barrier 36 and affecting the encapsulation effect.

Further, referring to FIG. 9 and FIG. 10 again, the first non-display sub-region 3 further includes a fourth region 39 located on a side of the second barrier 36 away from the first barrier 10. Along the direction perpendicular to the plane of the substrate 4, the first film layer 8 overlaps the second barrier 36 and does not overlap the fourth region 39.

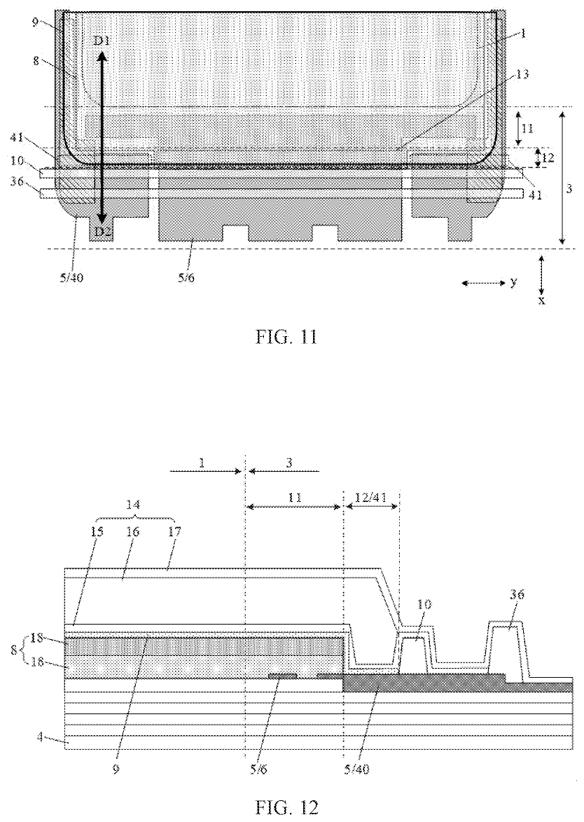

That is, the first film layer 8 extends to below the second barrier 36 and stops, and does not continue to extend outward, thereby preventing the side wall of the first film layer 8 from being exposed by the second inorganic encapsulation layer 17 to provide an infiltration path for water and oxygen, and thus ensuring a better encapsulation effect. FIG. 11 is schematic diagram of a display panel according to another embodiment of the present disclosure. FIG. 12 is a cross-sectional view of FIG. 11 along line D1-D2. As shown in FIG. 11 and FIG. 12, the first metal layer 5 further includes a second signal line 40 at least located in the first non-display region 3. The second signal line 40 is electrically connected to the cathode 9.

The second region 12 further includes a third sub-region 41. The third sub-region 41 includes a second signal line 40. It may also be understood as a region in which the second signal line 40 is disposed in the second region 12. Along the direction perpendicular to the plane of the substrate 4, the first film layer 8 does not overlap the third sub-region 41, and the cathode 9 overlaps the third sub-region 41 and is in contact with the second signal line 40 in the third sub-region 41.

In this configuration, the cathode 9 overlaps the second region 12. The first signal line 6 is disposed in the first sub-region 13 of the second region 12. However, since the first signal line 6 is covered with the first film layer 8, even if the cathode 9 overlaps the first signal line 6, the cathode 9 and the first signal line 6 will not be short-circuited. The second signal line 40 is disposed in the third sub-region 41 of the second region 12, thereby removing the first film layer 8 in the third sub-region 41, enabling the cathode 9 to be directly in contact with the second signal line 40 in this region, increasing the connection area between the cathode 9 and the second signal line 40, reducing the contact resistance, and improving the connection reliability.

In an embodiment, referring to FIG. 3, the non-display region 2 further includes two second non-display sub-regions 42 respectively located on two opposite sides of the display region 1 along the second direction y, and the second direction y intersects with the first direction x.

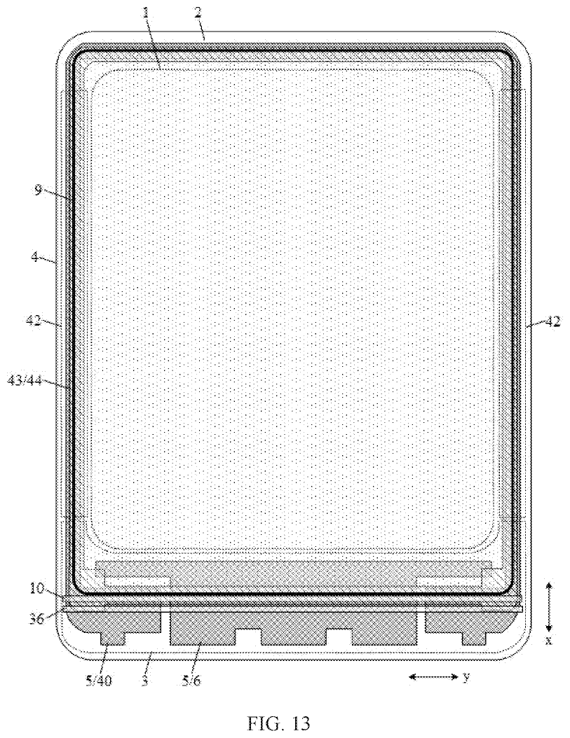

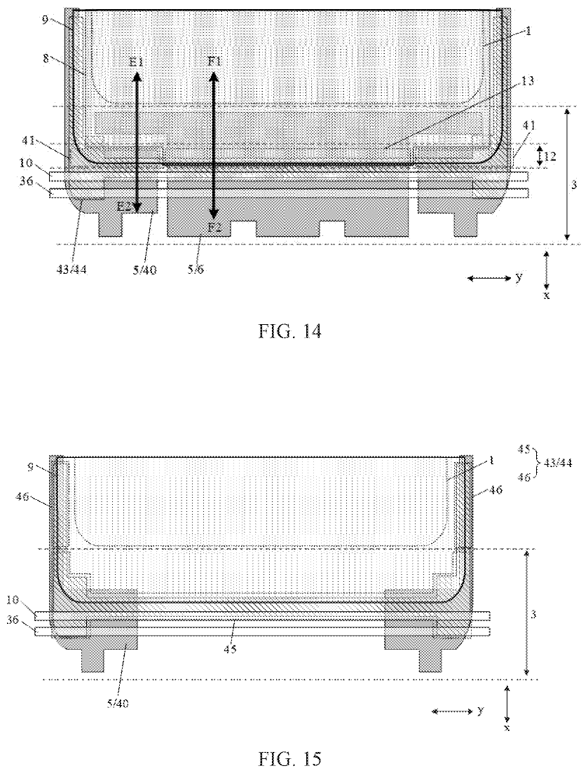

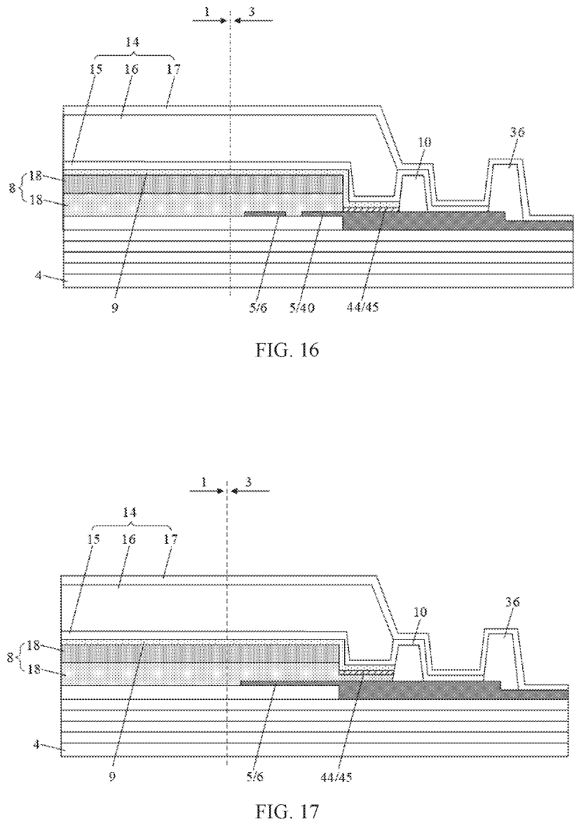

FIG. 13 is schematic diagram of a display panel according to another embodiment of the present disclosure. FIG. 14 is schematic diagram of a display panel according to another embodiment of the present disclosure. FIG. 15 is schematic diagram of a display panel according to another embodiment of the present disclosure. FIG. 16 is a cross-sectional view of FIG. 14 along line E1-E2. FIG. 17 is a cross-sectional view of FIG. 14 along line F1-F2. In combination with FIG. 3 and FIGS. 13-16, the first metal layer 5 further includes a second signal line 40 at least located in the first non-display region 3.

The display panel further includes a second metal layer 43 located between the first film layer 8 and the cathode 9. For example, the second metal layer 43 may be a metal layer where the anode 34 is located.

The second metal layer 43 includes a lapping electrode 44 located in the non-display region 2. The lapping electrode 44 is electrically connected to the cathode 9 and the second signal line 40, respectively.

The lapping electrode 44 includes a first electrode portion 45 and two second electrode portions 46. The two second electrode portions 46 are respectively located in the two second non-display sub-regions 42. The first electrode portion 45 is located in the first non-display region 3 and connected between the two second electrode portions 46. That is, the first electrode portion 45 laterally penetrates through the first non-display region 3.

In an embodiment of the present disclosure, as described above, the positions where the first signal lines 6 are arranged in the second region 12 are covered with the first film layer 8. Therefore, the two first electrode portions 45 located in the two second non-display sub-regions 42 may be connected by the first electrode portion 45 crossing the first non-display sub-region 3. Even if the first electrode portion 45 overlaps the first signal line 6, it will not be short-circuited with the first signal line 6.

The lapping electrode 44 continuously extends in the first non-display sub-region 3 and the second non-display sub-region 42, enabling a left-right penetration of the cathode signal. Additionally, along the direction perpendicular to the plane of the substrate 4, the cathode 9 may also overlap the first electrode portion 45, thereby achieving contact connection between the cathode 9 and the first electrode portion 45, increasing a contact area between the cathode 9 and the lapping electrode 44, and thus facilitating the transmission of the cathode signal.

In an embodiment, with reference to FIG. 14 to FIG. 16, the second region 12 further includes a third sub-region 41. The third sub-region 41 includes a second signal line 40. Along the direction perpendicular to the plane of the substrate 4, the first film layer 8 does not overlap the third sub-region 41, and the first electrode portion 45 is in contact with the second signal line 40 in the third sub-region 41.

The second signal line 40 is disposed in the third sub-region 41 of the second region 12. By removing the first film layer 8 in this region, the second signal line 40 can be exposed, thereby enabling the first electrode portion 45 and the second signal line 40 to be in contact connection, increasing the connection area between the first electrode portion 45 and the second signal line 40, and thus helping to reduce the contact resistance and to improve the connection reliability.

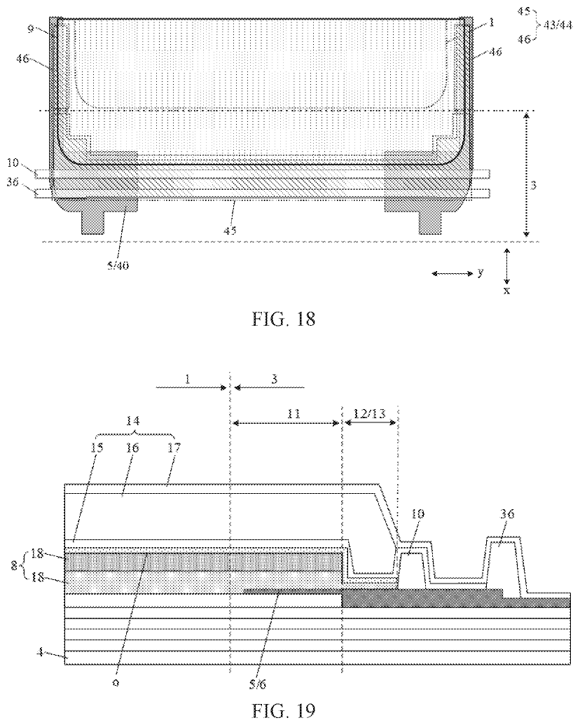

FIG. 18 is schematic diagram of a display panel according to another embodiment of the present disclosure. As shown in FIG. 18, the display panel further includes a second barrier 36 located on a side of the first barrier 10 away from the display region 1. Along the direction perpendicular to the plane of the substrate 4, an edge of the first electrode portion 45 overlaps the second barrier 36.

That is, a boundary of the first electrode portion 45 is pulled to below the second barrier 36. Then the first electrode portion 45 has a relatively large width. An overlapping region between the first electrode portion 45 and the second signal line 40 as well as the cathode 9 can be larger, further optimizing the display uniformity and reducing the power consumption. Additionally, the boundary of the first electrode portion 45 does not exceed the second barrier 36, which can also avoid affecting the encapsulation reliability.

In an embodiment, referring again to FIG. 6, the cathode 9 is located on a side of the second region 12 away from the first barrier 10, that is, an edge of the cathode 9 is located on a side of the second region 12 close to the display region 1. Along the direction perpendicular to the plane of the substrate 4, the cathode 9 does not overlap the second region 12, such that the cathode 9 does not fill in the pit structure of the second region 12, which helps the pit structure to have a larger depth to suppress the flow of the organic encapsulation material.

Further, a distance W between the cathode 9 and the second region 12 is smaller than 90 μm.

Based on the foregoing description of the related art, in the related art, when the distance between the boundary of the cathode film-forming region and the clearance region is smaller than or equal to 90 μm, the cathode evaporation material may easily extend into the clearance region, resulting in short circuit between the cathode and the first bus, thereby causing defects such as burnout and abnormal display. Therefore, in order to avoid the short circuit problem, in the related art, the distance between the boundary of the cathode film-forming region and the clearance region needs to be kept more than 90 μm. However, this would be contradictory to the design of the narrow frame, thereby limiting further narrowing of the frame.

However, in an embodiment of the present disclosure, since the first film layer 8 can be used to avoid the short circuit problem between the cathode 9 and the first signal line 6, the distance between the cathode 9 and the second region 12 can be compressed within 90 μm to help match the narrower frame design.

It should be noted that the first film layer 8 includes a first portion located in the first region 11 and a second portion located in the second region 12, a film thickness of the first portion is greater than a film thickness of the second portion, and the two portions have a virtual boundary based on the existence of the step difference. A distance between the cathode 9 and the second region 12 can be regarded as a distance between the cathode 9 and the virtual boundary.

In one design, referring to FIG. 6, along the first direction x, a distance between the cathode 9 and the second region 12 is W, a width of the second region 12 is B, a width of the first barrier 10 is C, a width of the third region 37 is D, and a width of the second barrier 36 is E. The design of W may satisfy W+B+C+D+E≥90 μm, for example, when B=20 μm, 20 μm≤C≤30 μm, 20 μm≤D≤30 μm, and 20 μm≤E≤30 μm, a minimum value of W+B+C+D+E is 100 μm. Therefore, there may be a safe distance between the edge of the cathode 9 and the fourth region 39, thereby preventing the cathode evaporation material from extending to a region outside the second barrier 36 and contacting the first signal line 6.

FIG. 19 is schematic diagram of a display panel according to another embodiment of the present disclosure. As shown in FIG. 19, along the direction perpendicular to the plane of the substrate 4, the cathode 9 overlaps the second region 12, and further overlaps the first sub-region 13.

This design can enlarge the distance between the edge of the cathode 9 and the display region 1. For example, under a certain frame width, when the cathode 9 overlaps the second region 12, the distance between the edge of the cathode 9 and the display region 1 can be larger, which can better eliminate deviations in film-forming position caused by incoming material precision and the manufacturing process, thereby optimizing the film-forming effect of the cathode 9. Alternatively, this design may realize a narrower frame design. For example, when the cathode 9 overlaps the second region 12 under a condition that the distance between the edge of the cathode 9 and the display region 1 is fixed, the width of the lower frame may be designed to be smaller.

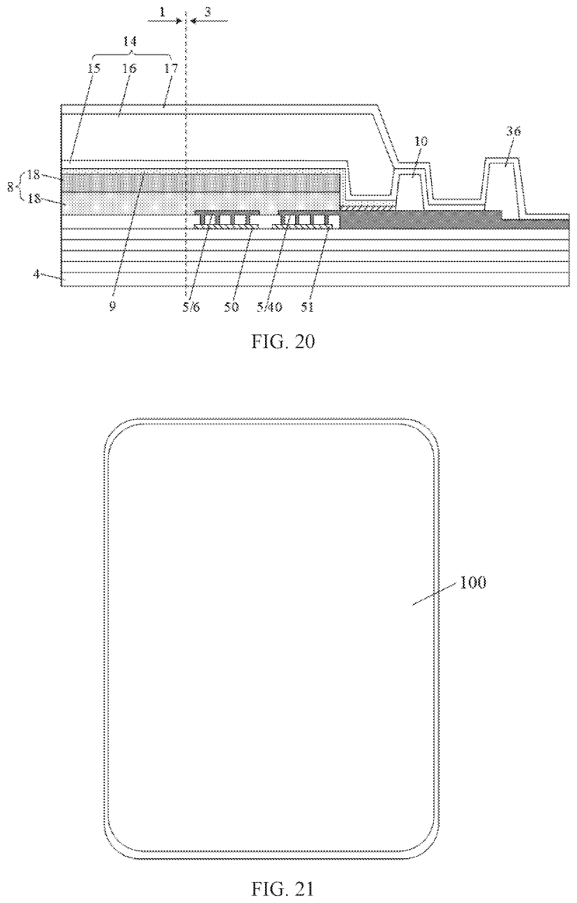

In an embodiment of the present disclosure, FIG. 20 is schematic diagram of a display panel according to another embodiment of the present disclosure. As shown in FIG. 20, in order to reduce the load of the first signal line 6 and the second signal line 40, the first signal line 6 may also be electrically connected to the first trace 50. The first trace 50 is located on a side of the first signal line 6 close to the substrate 4. The second signal line 40 may also be electrically connected to the second trace 51. The second trace 51 is located on a side of the second signal line 40 close to the substrate 4.

Based on the same inventive concept, an embodiment of the present disclosure further provides a display device, as shown in FIG. 21, which is a structural schematic diagram of a display device according to an embodiment of the present disclosure, and the display device includes the above display panel 100. It should be noted that the display device shown in FIG. 21 is merely illustrative, and the display device may be any electronic device having a display function such as a mobile phone, a tablet computer, a notebook computer, an e-book, and a television.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A display panel, comprising:
a display region and a non-display region, the non-display region comprising a first non-display sub-region, the first non-display sub-region being located on a side of the display region along a first direction;
a substrate;
a first metal layer located on a side of the substrate, wherein the first metal layer comprises a first signal line, the first signal line being located in the first non-display sub-region and transmitting a first signal;
a first film layer located on a side of the first metal layer away from the substrate, wherein the first film layer overlaps the display region and the first non-display sub-region along a direction perpendicular to a plane of the substrate;
a cathode located on a side of the first film layer away from the substrate, wherein the cathode is configured for transmitting a second signal, the second signal being different from the first signal, and the cathode overlaps the display region and the first sub-non-display region along the direction perpendicular to the plane of the substrate; and
a first barrier at least located in the first non-display region,
wherein the first non-display sub-region comprises a first region and a second region, and the display region, the first region, the second region and the first barrier are sequentially arranged along the first direction; and
wherein the second region comprises a first sub-region, the first sub-region comprises the first signal line, the first film layer overlaps the first region and the first sub-region along the direction perpendicular to the plane of the substrate, the first film layer at least overlaps the first signal line in the first sub-region, and a film thickness of the first film layer in the first sub-region is smaller than a film thickness of the first film layer in the first region.

2. The display panel according to claim 1, wherein:
the film thickness of the first film layer in the first sub-region is greater than or equal to 0.6 μm, and smaller than or equal to 1.1 μm.

3. The display panel according to claim 1, wherein:
the first film layer comprises at least two sub-layers, and a number of sub-layers comprised in the first sub-region is less than a number of sub-layers comprised in the first region.

4. The display panel according to claim 3, wherein:
the at least two sub-layers comprise a planarization layer and a pixel definition layer that are located on a side of the planarization layer away from the substrate; and
the first region comprises the planarization layer and the pixel definition layer, and the first sub-region comprises the planarization layer or the pixel definition layer.

5. The display panel according to claim 3, wherein:
in at least one of the at least two sub-layers, the sub-layer is a single-layer film structure, and a film thickness of the sub-layer in the first sub-region is smaller than a film thickness of the sub-layer in the first region.

6. The display panel according to claim 1, wherein:
the display panel further comprises a second barrier located on a side of the first barrier away from the display region; and
the first non-display sub-region further comprises a third region, the third region is located between the first barrier and the second barrier, the third region comprises a second sub-region, the second sub-region comprises the first signal line, the first film layer further overlaps the first signal line in the second sub-region along the direction perpendicular to the plane of the substrate, and a film thickness of the first film layer in the second sub-region is smaller than the film thickness of the first film layer in the first region.

7. The display panel according to claim 6, wherein:
the first non-display sub-region further comprises a fourth region located on a side of the second barrier away from the first barrier; and
the first film layer overlaps the second barrier and does not overlap the fourth region along the direction perpendicular to the plane of the substrate.

8. The display panel according to claim 1, wherein:
the first metal layer further comprises a second signal line at least located in the first non-display region, and the second signal line is electrically connected to the cathode; and
the second region further comprises a third sub-region, the third sub-region comprises the second signal line, the first film layer does not overlap the third sub-region along the direction perpendicular to the plane of the substrate, and the cathode overlaps the third sub-region and is in contact with the second signal line in the third sub-region.

9. The display panel according to claim 1, wherein:
the non-display region further comprises two second non-display sub-regions that are respectively located on two opposite sides of the display region along a second direction, and the second direction intersects with the first direction;
the first metal layer further comprises a second signal line at least located in the first non-display region;
the display panel further comprises a second metal layer, the second metal layer is located between the first film layer and the cathode, the second metal layer comprises a lapping electrode, and the lapping electrode is located in the non-display region and is electrically connected to the cathode and the second signal line respectively; and
wherein the lapping electrode comprises a first electrode portion and two second electrode portions, the two second electrode portions are respectively located in the two second non-display sub-regions, and the first electrode portion is located in the first non-display region and is connected between the two second electrode portions.

10. The display panel according to claim 9, wherein:
the second region further comprises a third sub-region, the third sub-region comprises the second signal line, the first film layer does not overlap the third sub-region along the direction perpendicular to the plane of the substrate, and the first electrode portion is in contact with the second signal line in the third sub-region.

11. The display panel according to claim 10, wherein:
the display panel further comprises a second barrier located on a side of the first barrier away from the display region; and
an edge of the first electrode portion overlaps the second barrier along the direction perpendicular to the plane of the substrate.

12. The display panel according to claim 1, wherein:
the cathode is located on a side of the second region away from the first barrier.

13. The display panel according to claim 12, wherein:
a distance between the cathode and the second region is smaller than 90 μm.

14. The display panel according to claim 1, wherein:
the cathode overlaps the second region along the direction perpendicular to the plane of the substrate.

15. A display device, comprising a display panel, wherein the display panel comprises:
a display region and a non-display region, the non-display region comprising a first non-display sub-region, the first non-display sub-region being located on a side of the display region along a first direction;
a substrate;
a first metal layer located on a side of the substrate, wherein the first metal layer comprises a first signal line, the first signal line being located in the first non-display sub-region and transmitting a first signal;
a first film layer located on a side of the first metal layer away from the substrate, wherein the first film layer overlaps the display region and the first non-display sub-region along a direction perpendicular to a plane of the substrate;
a cathode located on a side of the first film layer away from the substrate, wherein the cathode is configured for transmitting a second signal, the second signal being different from the first signal, and the cathode overlaps the display region and the first sub-non-display region along the direction perpendicular to the plane of the substrate; and
a first barrier at least located in the first non-display region,
wherein the first non-display sub-region comprises a first region and a second region, and the display region, the first region, the second region and the first barrier are sequentially arranged along the first direction; and
wherein the second region comprises a first sub-region, the first sub-region comprises the first signal line, the first film layer overlaps the first region and the first sub-region along the direction perpendicular to the plane of the substrate, the first film layer at least overlaps the first signal line in the first sub-region, and a film thickness of the first film layer in the first sub-region is smaller than a film thickness of the first film layer in the first region.
